(19) United States
(12) Patent Application Publication
(10) Pub. No.: US 2026/0165183 A1
(43) Pub. Date: Jun. 11, 2026

(54) INTEGRATED CIRCUIT DEVICE AND METHODS

(71) Applicants: TAIWAN SEMICONDUCTOR MANUFACTURING COMPANY, LTD., Hsinchu (TW); TSMC CHINA COMPANY, LIMITED, Shanghai (CN)

(72) Inventors: Xiaopeng ZHOU, Hsinchu (TW); Hongzhi ZHANG, Hsinchu (TW); Lan HUANG, Hsinchu (TW)

(21) Appl. No.: 18/983,642

(22) Filed: Dec. 17, 2024

(30) Foreign Application Priority Data
Dec. 10, 2024 (CN) 202411813544.X

(51) Int. Cl. H01L 23/00

(52) U.S. Cl. CPC H10W 72/90; H10W 72/019; H10W 72/29; H10W 72/923; H10W 72/942; H10W 72/981

(57) ABSTRACT

An integrated circuit (IC) device includes an interconnect layer including a first interconnect structure and a second interconnect structure spaced apart from the first interconnect structure in a first direction, the first interconnect structure and the second interconnect structure being arranged at a first pitch in the first direction; and a passivation structure on the first interconnect structure and the second interconnect structure. The passivation structure includes a first recess over the first interconnect structure; a second recess over the second interconnect structure; and a sloped region extending from the first recess to the second recess. A radius of curvature of a middle region of the sloped region is at least 0.5 times the first pitch.

### PRIORITY CLAIM

This application claims priority to Chinese Application No. 202411813544.X, filed Dec. 10, 2024, which is incorporated by reference herein in its entirety.

### BACKGROUND

As integrated circuit manufacturing process nodes have advanced, integrated circuits have become denser. Load carrying capacity of interconnect lines in these denser nodes is impacted by a thickness of the interconnect lines. The thickness of the interconnect lines also impacts resistance to signals propagating along the interconnect lines. In order to help maintain load carrying capacity and minimize resistance, top layer interconnect lines have an increased thickness, sometimes called ultra-thick metal (UTM) lines.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a plan view of an integrated circuit device, in accordance with some embodiments.

FIG. 2 is a cross-sectional view of an integrated circuit device corresponding to a line I-I′ in FIG. 1, in accordance with some embodiments.

FIG. 3A is a flowchart of a method of fabricating an integrated circuit device, in accordance with some embodiments.

FIGS. 3B-1 to 3B-5 are cross-sectional views of a portion of an interconnect structure at various stages in a method of fabricating an integrated circuit device, in accordance with some embodiments.

FIG. 4A is a schematic example of a thicknesses of a liner, passivation layers, and an interconnect structure, in accordance with some embodiments.

FIG. 4B is a schematic representation of a liner and bulk silicon oxide layers, in accordance with some embodiments.

FIG. 5A is a flow chart of a method for forming a passivation layer structure, in accordance with some embodiments.

FIG. 5B is an example of a path that a wafer travels in a manufacturing tool, in accordance with some embodiments.

FIG. 6 is a cross-sectional view of the integrated circuit device corresponding to a line I-I′ in FIG. 1, in accordance with some embodiments.

FIG. 7 is a schematic cross-sectional view of stresses in an interconnect structure, in accordance with some embodiments.

FIGS. 8A and 8B are schematic cross-sectional views of an intermediate structure of an integrated circuit device, in accordance with some embodiments.

FIG. 8C is a schematic cross-sectional view of an intermediate structure of an integrated circuit device, in accordance with some embodiments.

FIG. 9 is a block diagram of an IC device, in accordance with some embodiments.

FIG. 10 is a block diagram of an electronic design automation (EDA) system in accordance with some embodiments.

FIG. 11 is a block diagram of an integrated circuit (IC) manufacturing system, and an IC manufacturing flow associated therewith, in accordance with some embodiments.

### DETAILED DESCRIPTION

The following disclosure provides many different embodiments, or examples, for implementing different features of the provided subject matter. Specific examples of components, values, steps, operations, materials, arrangements, or the like, are described below to simplify the present disclosure. These are, of course, merely examples and are not intended to be limiting. Other components, values, operations, materials, arrangements, or the like, are contemplated. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of a device in use or operation in addition to the orientation depicted in the figures. The device may be otherwise oriented (rotated 90 degrees or at other orientations) and the spatially relative descriptors used herein may likewise be interpreted accordingly.

As semiconductor device technology nodes continue to shrink, interconnect structures tend to be made smaller. Some conductive features, however, are maintained relatively larger to provide mechanical strength, current-carrying capabilities, and the like. Such relatively larger structures result in larger stresses due to thermal expansion and/or contraction.

For a material with a positive coefficient of thermal expansion (CTE), increasing a dimension ‘L’ of a structure formed of the material will result in a correspondingly increased temperature-based change in the dimension, ΔL, as the structure is heated (resulting in expansion) or cooled (resulting in contraction). For example, for a first structure having a length L1 and a second structure having a length L2 that is greater than L1, a temperature-based change in length ΔL1 of the first structure as a result of a given temperature increase ΔT will be less than the temperature-based change in length ΔL2 of the second structure for the temperature increase ΔT, if the first and second structures are formed of the same material.

Larger stresses due to thermal expansion and/or contraction present greater challenges as these structure sizes are increased (or, not reduced in size as much as other structures in the device), e.g., when forming an ultra-thick metal layer (UTM layer) in an IC device interconnect structure. In a device in which a UTM structure adjoins a passivation structure such as a high-density plasma (HDP) passivation structure, the metal expansion/contraction in the UTM structure upon heating/cooling is relatively large as compared to a structure in a thinner metal layer. Likewise, the passivation structure expansion/contraction is relatively large as compared to an insulating structure in a thinner insulating layer.

In the case of contraction due to cooling, the contraction of the UTM structure effectively results in an overall reduction in size of the UTM structure proportional to its CTE and the temperature change. Likewise, the contraction of the passivation structure results in an overall reduction in size of the passivation structure proportional to its CTE and the temperature change. In some device structures, shrinkage of the UTM structure causes the UTM structure to pull away from the passivation structure at the same time that shrinkage of the passivation structure causes the passivation structure to pull away from the UTM structure, potentially resulting in separation of the UTM structure from the passivation structure or splitting (cracking) of the passivation structure. The present disclosure provides IC devices with reduced tendency for cracking and methods of fabricating the same.

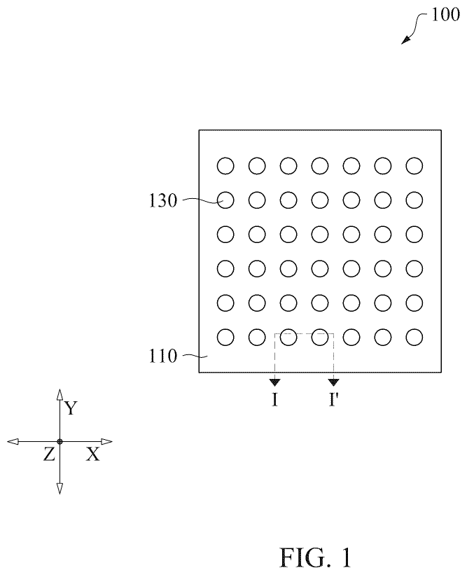

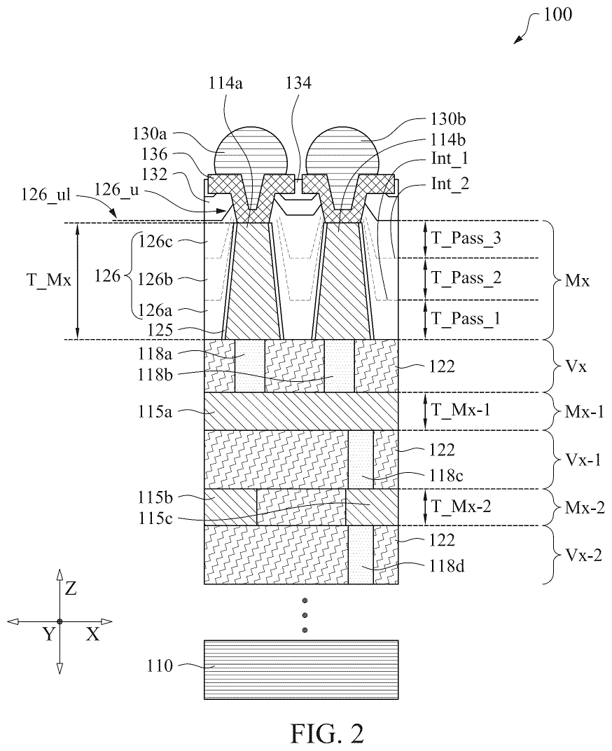

FIG. 1 is a plan view of an integrated circuit device 100, in accordance with some embodiments. FIG. 2 is a cross-sectional view of the integrated circuit device 100 corresponding to a line I-I′ in FIG. 1, in accordance with some embodiments.

In FIGS. 1 and 2, an IC device 100 in accordance with some embodiments includes a substrate 110 and conductive bumps 130 at a surface of the substrate 110. Referring to FIG. 2, the IC device 100 includes interconnect layers Mx, Mx−1, and Mx−2 (collectively, interconnect layers M) over the substrate 110, and conductive bumps 130a and 130b over the interconnect layers M.

In some embodiments, the substrate 110 is a semiconductor substrate. In some embodiments, the substrate 110 is a silicon substrate, a silicon-germanium substrate, a silicon carbide substrate, a gallium arsenide substrate, or the like. In some embodiments, the substrate 110 includes another elementary semiconductor, such as germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. In some embodiments, the substrate 110 is a semiconductor-on-insulator (SOI) substrate. In some embodiments, the substrate 110 includes a doped epi layer, a gradient semiconductor layer, and/or a semiconductor layer overlying another semiconductor layer of a different type, such as a silicon layer on a silicon germanium layer. In some embodiments, the substrate 110 includes doped regions such as a p-well, an n-well, or both. In some embodiments, the substrate 110 is a dielectric substrate, a sapphire substrate, or the like.

The interconnect layers M include interconnect layer Mx, interconnect layer Mx−1 between the interconnect layer Mx and the substrate 110, and interconnect layer Mx−2 between the interconnect layer Mx−1 and the substrate 110. The interconnect layers M are conductive and include conductive structures, e.g., metal interconnect structures. In the IC device 100, the interconnect layer Mx is a topmost interconnect layer of the interconnect layers M. In some embodiments, interconnect structures in the interconnect layer Mx serve as input/output (I/O) pads or power pads. FIG. 2 includes interconnect structures 114a and 114b. The interconnect structures 114a and 114b (and/or any other interconnect structures in the interconnect layer Mx) are collectively referred to as interconnect structures 114.

In some embodiments, the interconnect layers M, and thus the interconnect structures 114, are formed of or include conductive materials such as one or more of aluminum, titanium, titanium nitride, tantalum nitride, cobalt, silver, gold, copper, nickel, chromium, hafnium, ruthenium, tungsten, platinum, or the like. In some embodiments, the interconnect layers M are formed of substantially pure copper (e.g., with a weight percentage of copper being greater than about 90 percent, or greater than about 95 percent). In some embodiments, the interconnect layers M are formed of copper alloys. In some embodiments, the interconnect structures 114 are formed using a damascene or dual damascene method. In other embodiments, one or more of the interconnect layers M includes a different conductive material from one or more others of interconnect layers M.

Structures formed in the interconnect layers M generally extend in alternating X-axis and Y-axis directions. For example, in some embodiments, interconnect structures in the interconnect layer Mx generally extend in the Y-axis direction, interconnect structures in the interconnect layer Mx−1 generally extend in the X-axis direction, and interconnect structures in the interconnect layer Mx−2 generally extend in the Y-axis direction. In other embodiments, interconnect structures in the interconnect layer Mx generally extend in the X-axis direction, interconnect structures in the interconnect layer Mx−1 generally extend in the Y-axis direction, and interconnect structures in the interconnect layer Mx−2 generally extend in the X-axis direction.

In FIG. 2, the interconnect structures 114 have a trapezoidal shape. In other embodiments, the interconnect structures 114 are rectangular, curved, or another shape. In some embodiments, the interconnect structures 114 taper toward the top as in FIG. 2, whereas in other embodiments the interconnect structures 114 do not taper or taper towards the bottom. Embodiments are not limited to a particular shape of the interconnect structures 114.

The IC device 100 includes interconnect structure 115a in the interconnect layer Mx−1, and interconnect structures 115b and 115c in the interconnect layer Mx−2. In some instances, the interconnect structures 115a, 115b, and 115c are referred to generically and/or collectively as interconnect structures 115.

The interconnect structures 114a and 114b are spaced apart from each other in the X-axis direction, which is generally parallel to a major surface of the substrate 110. The interconnect structures 115b and 115c are also spaced apart from each other in the X-axis direction.

In FIG. 2, the interconnect layer Mx is thicker (i.e., has a greater height in the Z-axis direction, which is orthogonal to the X-axis direction and generally normal to the major surface of the substrate 110) than the interconnect layers Mx−1 and Mx−2. That is, a thickness T_Mx of the interconnect layer Mx is greater than a thickness T_Mx−1 of the interconnect layer Mx−1, and is greater than a thickness T_Mx−2 of the interconnect layer Mx−2. The interconnect layer Mx is referred to herein as an ultra-thick metal layer (UTM layer). The interconnect structures 114 are referred to herein as ultra-thick metal structures (UTM structures).

In some embodiments, the interconnect layer Mx (UTM layer) helps to provide additional load-carrying capacity for interconnect lines. The increased thickness of the UTM layer relative to the other, underlying interconnect layers helps to increase current-carrying capacity of the interconnects by reducing resistance, and helps to prevent breakage caused by too thin of a line width. Also, the increased thickness of the UTM layer improves the performance of integrated circuit components such as inductors to meet performance requirements in circuits such as mixed-signal circuits, analog circuits, and radio frequency (RF) circuits.

In some embodiments, the interconnect layer Mx is significantly thicker than the other, underlying interconnect layers (Mx−1, Mx−2, and the like). In some embodiments, the interconnect layer Mx is formed to have a thickness of about 8500 Angstroms (8.5K Å) to about 40K Å. Decreasing the thickness of the interconnect layer Mx below 8.5K Å reduces current-carrying capacity of structures in the interconnect layer Mx in some instances. Increasing the thickness of the interconnect layer Mx beyond 40K Å increases device thickness in some instances. In some embodiments, the underlying interconnect layers (Mx−1, Mx−2, and the like) are formed to have a thickness of about 1K Å to about 8K Å. Decreasing the thickness of the underlying interconnect layers (Mx−1, Mx−2, and the like) below 1K Å results in fragile structures in the underlying interconnect layers in some instances. Increasing the thickness of the underlying interconnect layers beyond 8K Å increases device thickness in some instances. In some embodiments, the interconnect layer Mx is about 5 times thicker, or more, than any of the other, underlying interconnect layers (e.g., Mx−1, Mx−2, and the like). In some embodiments, the interconnect layer Mx is about 10 times thicker, or more than any of the other, underlying interconnect layers (e.g., Mx−1, Mx−2, and the like). A thickness ratio of about 5 times or more, e.g., about 10 times or more, helps to enhance the current-carrying ability of the interconnect layer Mx relative to the underlying interconnect layers in some instances. In some embodiments, the interconnect layers Mx−1 and Mx−2 are each a same thickness, and are both thinner than the interconnect layer Mx. In other embodiments, the interconnect layer Mx−1 is a different thickness than the interconnect layer Mx-2, and are both thinner than the interconnect layer Mx. It will be appreciated that dimensions, ratios, and statements of relative scale that are provided for the interconnect layers and/or other structures are merely examples, and are different in other embodiments.

The IC device 100 includes via layers Vx, Vx−1, and Vx−2 (collectively, via layers V) alternating with the interconnect layers M, and electrically connecting structures in the interconnect layers M. In FIG. 2, via layer Vx is between the interconnect layer Mx and the interconnect layer Mx−1. Via layer Vx includes a via 118a and a via 118b. Via layer Vx−1 is between the interconnect layer Mx−1 and the interconnect layer Mx−2. Via layer Vx−1 includes a via 118c. Via layer Vx−2 is between the interconnect layer Mx−2 and the substrate 110. Via layer Vx−2 includes a via 118d. The vias 118a, 118b, 118c, and 118d are referred to generically and/or collectively as vias 118. In some embodiments, the vias 118 are formed of or include conductive materials such as one or more of aluminum, titanium, titanium nitride, tantalum nitride, cobalt, silver, gold, copper, nickel, chromium, hafnium, ruthenium, tungsten, platinum, or the like. In some embodiments, one or more of the vias 118 includes a different conductive material from one or more others of the vias 118.

In the interconnect layers M and the via layers V, an insulating material 122 fills spaces between the interconnect structures and the via structures.

In some embodiments, the insulating material 122 is or includes one or more of SiNₓ, SiOx, SiON, SiC, SiCN, SiBN, SiCBN, BN, borophosphosilicate glass (BPSG), tetraethyl orthosilicate (TEOS), spin-on glass (SOG), undoped silicate glass (USG), fluorinated silicate glass (FSG), high-density plasma (HDP) oxide, plasma-enhanced TEOS (PETEOS), or the like. In some embodiments, the insulating material 122 is formed by one or more of chemical vapor deposition (CVD), plasma-enhanced chemical vapor deposition (PE-CVD), physical vapor deposition (PVD), atomic layer deposition (ALD), spin-on coating, or the like. In some embodiments, a same insulating material is used for each of the interconnect layers M and via layers V. In other embodiments, one or more of the interconnect layers M and/or via layers V includes a different insulating material from one or more others of the interconnect layers M and/or via layers V.

In FIG. 2, the IC device 100 includes three interconnect layers Mx, Mx−1, and Mx−2 over the substrate 110. In other embodiments, the number of interconnect layers is greater than three or less than three. In some embodiments, the interconnect layer Mx, i.e., the UTM layer, is an M5 metal layer, where M5 refers to the sixth metal layer in a sequence of metal layers M0, M1, M2, M3, M4, and M5, with M0 being the first metal layer over the MD layer, and where the MD layer is a conductive layer (also referred to as a metal-over-diffusion layer) forming source/drain contacts directly on the active region and at a same level as a poly layer (gate layer). In other embodiments, the UTM layer is topmost interconnect layer at, e.g., the M4, M3, or M2 level, or a topmost interconnect layer at a level above M5.

The IC device 100 includes a passivation layer structure 126 on sidewalls of the interconnect structures 114a and 114b. In FIG. 2, the passivation layer structure 126 includes three layers, namely passivation layers 126a, 126b, and 126c. In other embodiments, the number of passivation layers is different from three. A passivation layer structure including a higher number of passivation layers (e.g., four passivation layers) creates additional interfaces in the passivation layer, which increases a likelihood of cracking in some instances. A passivation layer structure including a lower number of passivation layers (e.g., two passivation layers) increases process time to form each layer and impacts a thermal budget of device structures in some instances. The passivation layer 126a is between the passivation layer 126b and the interconnect layer Mx. The passivation layer 126b is between the passivation layer 126a and the passivation layer 126c. An interface of the passivation layer 126a with the passivation layer 126b is referred to herein as a first interface Int_1. An interface of the passivation layer 126b with the passivation layer 126c is referred to herein as a second interface Int_2.

In the IC device 100, a liner 125 is on sidewalls of the interconnect structures 114a and 114b, between the sidewalls of the interconnect structures 114a and 114b and the passivation layer 126a. In some embodiments, the liner is not present at the first interface Int_1 or the second interface Int_2. The liner 125 is described in further detail below.

In FIG. 2, the passivation layer structure 126 has a thickness sufficient to cover the sidewalls of the interconnect structures 114a and 114b. In some embodiments, an overall height (in the Z-axis direction) of the passivation layer structure 126 is greater than an overall height of the interconnect structures 114a and 114b. In some embodiments, a minimum height (in the Z-axis direction) of the passivation layer structure 126 is greater than an overall height of the interconnect structures 114a and 114b. In some embodiments, the passivation layer structure 126 covers portions of tops of the interconnect structures 114a and 114b. The passivation layer structure 126 has an upper surface 126_u. In FIG. 2, the upper surface 126_u has a lowermost extent 126_ul that is above the tops of the interconnect structures 114a and 114b. That is, the lowermost extent 126_ul is higher (in the Z-axis direction) than the uppermost extent of the interconnect structures 114a and 114b. In some instances, maintaining the lowermost extent 126_ul of the upper surface 126_u above the tops of the interconnect structures 114a and 114b helps to reduce stress concentrations in the passivation layer structure 126, and helps to prevent cracking or separation of the passivation layer structure 126. In other embodiments, the lowermost extent 126_ul of the upper surface 126_u of the passivation layer structure 126 is at an even height with or below the tops of the interconnect structures 114a and 114b.

In FIG. 2, relative to the Z-axis direction, a combined distance of: (i) a distance between the first interface Int_1 and a bottom of the interconnect layer Mx (adjacent to the via layer Vx), (ii) a distance between the second interface Int_2 and the first interface Int_1, and (iii) a distance between a top of the passivation layer 126c and the second interface Int_2 is equal to at least the height of the interconnect layer Mx and thus to at least the height of the interconnect structures 114a and 114b. In FIG. 2, the distance (i) is indicated as thickness T_Pass_1, the distance (ii) is indicated as thickness T_Pass_2, and the distance (iii) is indicated as thickness T_Pass_3. The sum of the thickness T_Pass_1, the thickness T_Pass_2, and the thickness T_Pass_3 is equal to at least the thickness T_Mx of the interconnect layer Mx. In some embodiments, the sum of the thickness T_Pass_1, the thickness T_Pass_2, and the thickness T_Pass_3 is greater than the thickness T_Mx of the interconnect layer Mx. In some embodiments, the nominal deposition thickness of the passivation layer 126a is the thickness T_Pass_1, the nominal deposition thickness of the passivation layer 126b is the thickness T_Pass_2, and the nominal deposition thickness of the passivation layer 126c is the thickness T_Pass_3. In some embodiments, the thicknesses T_Pass_1, T_Pass_2, and T_Pass_3 are substantially equal, such that the second interface Int_2 is twice the distance from the bottom of the interconnect layer Mx than the first interface Int_1. In other embodiments, one or more of the thicknesses T_Pass_1, T_Pass_2, and T_Pass_3 is different, e.g., T_Pass_2 is greater than T_Pass_1 and greater than T_Pass_3.

In some embodiments, the passivation layer structure 126 is a silicon oxide structure, e.g., a plurality of silicon oxide layers. In some embodiments, the passivation layer structure 126 includes a plurality of silicon oxide layers deposited using chemical vapor deposition (CVD). In some embodiments, one or more silicon oxide layers of the plurality of silicon oxide layers are deposited using high-density plasma (HDP) CVD. In other embodiments, the passivation layer structure 126 includes dielectric materials such as polyimide (PI), benzocyclobutene (BCB), polybenzoxazole (PBO), silicon nitride (SiN), silicon carbide (SiC), silicon oxynitride (SiON), low-k dielectrics such as carbon-doped oxides, extremely low-k dielectrics such as porous carbon-doped silicon dioxide, combinations thereof, or the like.

In FIG. 2, the IC device 100 includes an oxide layer 132 on the passivation layer structure 126. In some embodiments, the oxide layer 132 is a layer of silicon oxide that is formed using plasma-enhanced chemical vapor deposition (PECVD). In some embodiments, the oxide layer 132 is an SiOₓ layer that is deposited using PECVD using tetraethoxysilane (TEOS).

In FIG. 2, the IC device 100 includes a nitride layer 134 on the oxide layer 132. In some embodiments, the nitride layer 134 is included in the IC device 100 to help reduce or prevent damage or other undesired effects on the integrated circuits or package from moisture, mechanical stresses, and/or radiation. In some embodiments, the nitride layer 134 is a layer of silicon nitride (SiN) that is formed using PECVD. In some embodiments, the nitride layer 134 includes SiN or silicon oxynitride (SiON).

Openings, over tops of the interconnect structures 114a and 114b, are formed to penetrate the nitride layer 134, the oxide layer 132, the passivation layer structure 126, and the liner 125. In some embodiments, the openings are formed using a patterning technique such as photolithography. A conductive bump 130a vertically overlaps the interconnect structure 114a and is in electrical contact therewith through one of the openings. A conductive bump 130b vertically overlaps the interconnect structure 114b and is in electrical contact therewith through another of the openings. The conductive bumps 130a and 130b are referred to collectively as conductive bumps 130.

The IC device 100 includes under-bump metallization or under-ball metal (UBM) pads 136 in the openings. The UBM pads 136 provide electrical connectivity between the interconnect structures 114 and the conductive bumps 130. In some embodiments, the UBM pads 136 are or include one or more of gold, silver, copper, nickel, tungsten, aluminum, palladium, or the like. In some embodiments, the UBM pads 136 include more than one layer, e.g., an adhesion layer contacting the corresponding interconnect structure 114a or 114b of the interconnect layer Mx, a barrier layer on the adhesion layer, and a wetting layer on the barrier layer. In some embodiments, the UBM pads 136 include multiple layers of conductive materials, such as a layer of titanium, a layer of copper, and/or a layer of nickel. In some embodiments, the UBM pads 136 are omitted.

In some embodiments, the conductive bumps 130a and 130b provide electrical connections to another IC device (e.g., a die) within a same package or in a different package, or to an interposer, a printed circuit board (PCB), or the like. In some embodiments, the conductive bumps 130 are formed of or include one or more of solder, copper, nickel, gold, or the like. In some embodiments, the conductive bumps 130 are structures such as solder balls, ball grid array (BGA) balls, controlled collapse chip connection (C4) bumps, pillars, or the like. In some embodiments, the conductive bumps 130 have a shape that is spherical, hemispherical, cylindrical, or another suitable shape. In some embodiments, the formation of the conductive bumps 130 includes performing a plating step to form solder regions over the UBM pads 136, and then reflowing the solder regions to form the conductive bumps 130 on the UBM pads 136.

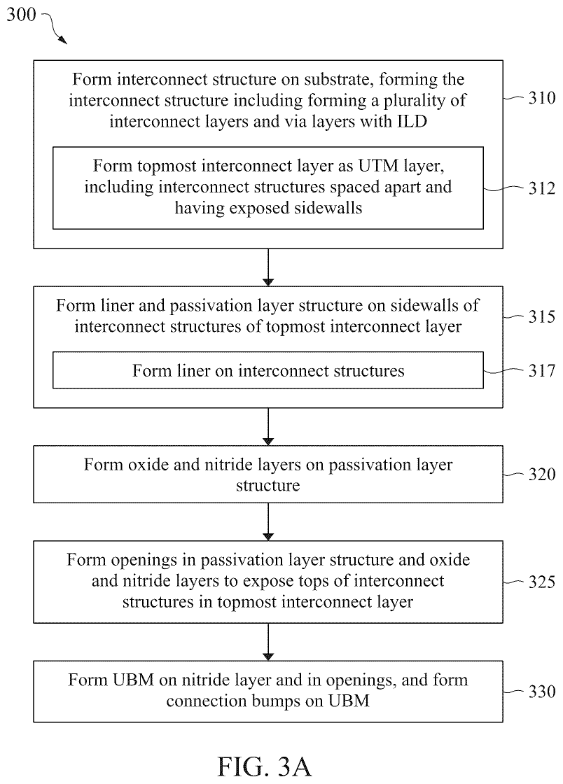

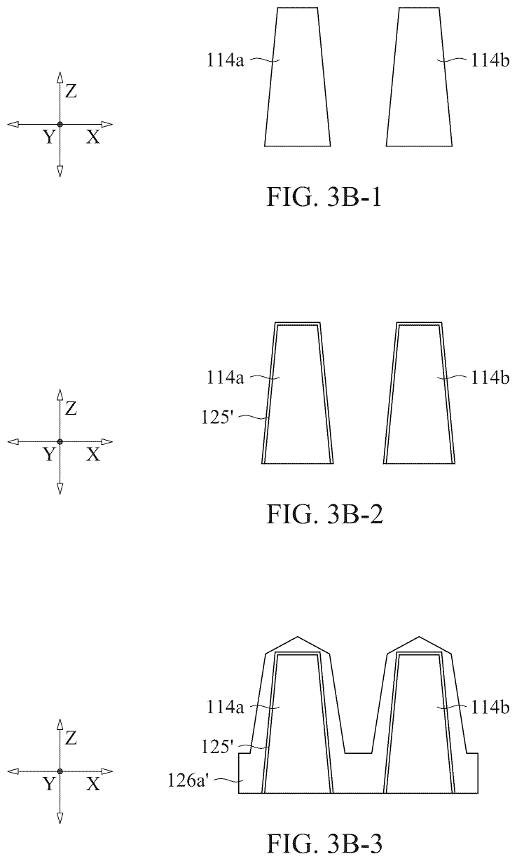

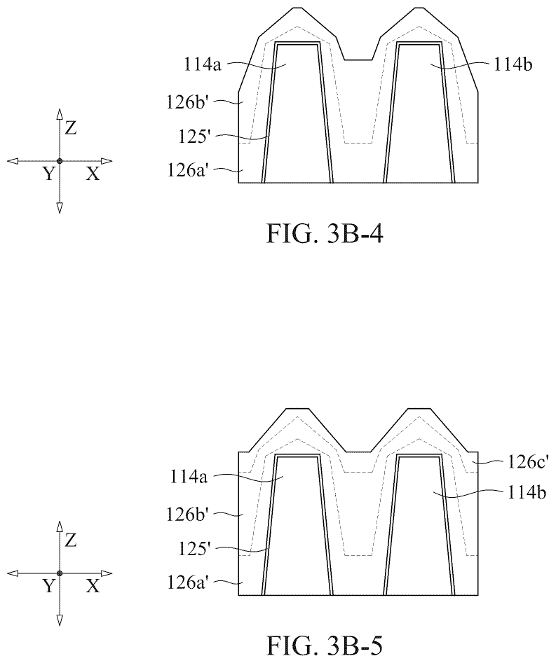

FIG. 3A is a flowchart of a method 300 of fabricating an integrated circuit device, in accordance with some embodiments.

The method 300 is an example of a method of fabricating the IC device 100. The method 300 is also usable to form IC devices other than the IC device 100. The method 300 includes blocks 310, 315, 320, 325, and 330. Block 310 includes block 312. Block 315 includes block 317.

In block 310, an interconnect structure is formed on a substrate. Forming the interconnect structure includes forming a plurality of alternating interconnect layers and via layers, and forming an insulating material around interconnect structures and vias. In block 312, forming the interconnect layers includes forming a topmost interconnect layer as a UTM layer, including forming UTM interconnect structures that are spaced apart and have exposed sidewalls. The topmost interconnect layer (the UTM layer) is formed to be thicker than the underlying interconnect layers. In some embodiments, the topmost interconnect layer (the UTM layer) is formed to be about 5 times thicker, or more, than any of the other, underlying interconnect layers (e.g., Mx−1, Mx−2, and the like). In some embodiments, the topmost interconnect layer (the UTM layer) is formed to be about 10 times thicker, or more than any of the other, underlying interconnect layers (e.g., Mx−1, Mx−2, and the like). A thickness ratio of about 5 times or more, e.g., about 10 times or more, helps to enhance the current-carrying ability of the topmost interconnect layer (the UTM layer) relative to the underlying interconnect layers in some instances.

The method 300 continues with block 315 in which a liner is formed on sidewalls and tops of the interconnect structures of the topmost interconnect layer, and a passivation layer structure is formed on the liner. The passivation layer structure is formed to have a thickness in a direction normal to the substrate that is sufficient to cover at least the sidewalls of the interconnect structures.

In block 315, forming the passivation layer structure includes depositing one or more passivation layers, e.g., three or more passivation layers. In some embodiments, the passivation layer(s) include(s) one or more silicon oxide layer(s). In some embodiments, one or more silicon oxide layers are deposited using chemical vapor deposition (CVD). In some embodiments, one or more silicon oxide layers are deposited using high-density plasma (HDP) CVD. In other embodiments, forming the passivation layer structure includes depositing dielectric materials such as polyimide (PI), benzocyclobutene (BCB), polybenzoxazole (PBO), silicon nitride (SiN), silicon carbide (SiC), silicon oxynitride (SiON), low-k dielectrics such as carbon-doped oxides, extremely low-k dielectrics such as porous carbon-doped silicon dioxide, combinations thereof, or the like.

In some embodiments, block 315 includes forming three passivation layers in sequence, i.e., forming a first passivation layer, forming a second passivation layer on the first passivation layer, and forming a third passivation layer on the second passivation layer. Block 315 includes, before forming the first passivation layer, an operation of forming the liner using an un-biased deposition operation. In some embodiments, second and third passivation layers are formed without the un-biased liner, such that the second passivation layer is formed directly on and thus directly contacts the first passivation layer, and the third passivation layer is formed directly on and thus directly contacts the second passivation layer.

FIGS. 3B-1 to 3B-5 are cross-sectional views of a portion of an interconnect structure at various stages in a method of fabricating an integrated circuit device, in accordance with some embodiments.

The intermediate structure in FIGS. 3B-1 is an example of a structure formed in block 312, in accordance with some embodiments. The intermediate structures in FIGS. 3B-2 through 3B-5 are examples of structures formed in block 315, in accordance with some embodiments.

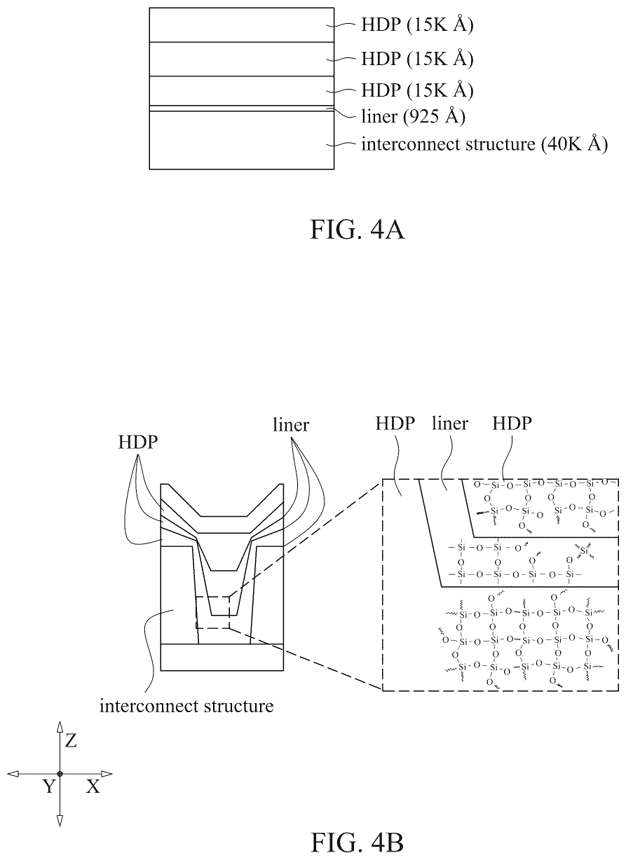

In FIG. 3B-1, interconnect structures 114a and 114b of a topmost interconnect layer Mx are formed (underlying layers are omitted for clarity). In FIG. 3B-2, liner 125′ is formed on exposed sidewalls and top surfaces of the interconnect structures 114a and 114b. In some embodiments, the liner 125′ is a silicon oxide layer formed by CVD without using bias. Forming the liner 125′ without using bias helps to avoid damaging exposed metal surfaces of the interconnect structures 114a and 114b. In FIG. 3B-3, passivation layer 126a′ is formed on liner 125′. In FIG. 3B-4, passivation layer 126b′ is formed on passivation layer 126a′. In FIG. 3B-5, passivation layer 126c′ is formed on passivation layer 126b′. In subsequent processing operations, an opening (vertically overlapping the interconnect structures 114a and 114b, for the UBM) is formed in the liner 125′ and the passivation layers 126a′, 126b′, and 126c′, resulting in the liner 125 and the passivation layers 126a, 126b, and 126c.

In some embodiments, bias is used in the formation of the passivation layers 126a′, 126b′, and 126c′, which, in some instances, are formed as bulk layers of SiO₂ using HDP CVD. CVD precursors for forming SiO₂ include silane and oxygen, and other suitable precursors.

Referring again to block 315 of the method 300, Table 1 below is an example of operations that form the liner and the first, second, and third passivation layers.

TABLE 1

| | Un-biased | |
|---|---|---|
| Operation | liner (n1) | Bulk layer (n2) |
| 1^{st} | 925 Å | D/S = 2.8 + 2.8 + 6.0 (15K Å) |
| 2^{nd} | — | D/S = 2.8 + 2.8 + 6.0 (15K Å) |
| 3^{rd} | — | D/S = 2.8 + 2.8 + 6.0 (15K Å) |

In Table 1, D/S refers to deposition rate/sputter rate. Note n1: un-biased liner is SiO₂ formed by CVD without using bias. Note n2: bulk layer is SiO₂ formed by HDP CVD; D/S 2.8+2.8+6.0 indicates that HDP layer-forming operation is three steps, as follows. First, using D/S=2.8 to form a first film. Next, using D/S=2.8 to form a second film. Next, using D/S=6.0 to form a third film.

In Table 1, an example liner thickness of 925 Å and example passivation layer thicknesses of 15K Å are given for an interconnect structure in the UTM layer (see interconnect structures 114a and 114b) having a thickness (see T_Mx) of 40K Å. This is illustrated schematically in FIG. 4A, in which the interconnect structure having a thickness of 40K Å is formed, and then the un-biased liner is formed to a thickness of 925 Å on the interconnect structure. Subsequently, the first, second, and third passivation layers are formed to thicknesses of 15K Å each, without a liner between the first and second passivation layers and without a liner between the second and third passivation layers. It will be understood that the stated thicknesses for the liner, the UTM layer, and the passivation layers are merely examples. The liner is thicker than 925 Å in some embodiments and is thinner than 925 Å in other embodiments. For example, in some embodiments the liner is about 700 Å to about 1300 Å. The UTM layer is thicker than 40K Å in some embodiments and is thinner than 40K Å in other embodiments. The passivation layers are thicker than 15K Å in some embodiments and thinner than 15K Å in other embodiments. For example, in some embodiments one or more of the passivation layers is about 5K Å to about 20K Å. The passivation layers all have a same thickness in some embodiments. The passivation layers each have different thicknesses in some embodiments. Two passivation layers have a same thickness and a third passivation layer has a different thickness in some embodiments. Relative thicknesses of the liner, the UTM layer, and the passivation layers can be freely varied.

In Table 1, each of the three passivation layers is formed to have a same thickness using the same D/S values. However, one, two, or all three of the passivation layers are formed to have a different thickness and/or formed using different D/S values in some embodiments.

In Table 1, the first operation forms the first passivation layer with an un-biased liner. Using the un-biased liner reduces a risk of damaging metal structures (e.g., the interconnect structures having exposed sidewalls) by biased RF sputter during a HDP process.

The second and third operations form the second and third passivation layers without the liner. Forming the second and third passivation layers without the liner avoids creating a liner interface, which is believed to be relatively weak and thus a potential promoter of crack formation. That is, the interface of the second passivation layer with the first passivation layer, and the interface of the third passivation layer with the second passivation layer, are made stronger by omitting the liner formation from the second and third operations. Without being bound by theory, it is believed that the unbiased liner is a relatively porous silicon oxide structure as compared to the relatively dense silicon oxide structure of the HDP CVD bulk layers. This is illustrated schematically in FIG. 4B, in which relatively porous liners are formed prior to formation of each relatively dense HDP bulk layer. It is believed that omitting the relatively porous liner between the relatively dense first and second passivation layers, and from between the relatively dense second and third passivation layers helps to reduce the possibility of separation or crack development between the first and second passivation layers, and between the second and third passivation layers.

In another example, the block 315 operations include (after forming a metallization feature in an inter-metal dielectric (IMD) layer, and forming a metal line over the metallization feature and the IMD layer): (i) forming a dielectric liner on the metal line and the IMD layer without using a bias voltage; (ii) forming a first passivation film on the dielectric liner using a bias voltage and a ratio of a deposition rate to a sputter rate, wherein the ratio is 2.8±0.2, 2.8±0.2, and 3.6±0.2 in sequence; (iii) forming a second passivation film on the first passivation film using a bias voltage and a ratio of a deposition rate to a sputter rate, wherein the ratio is 2.8±0.2, 2.8±0.2, and 3.6±0.2 in sequence; and (iv) forming a third passivation film on the second passivation film using a bias voltage and a ratio of a deposition rate to a sputter rate, wherein the ratio is 2.8±0.2, 2.8±0.2, and 3.6±0.2 in sequence, the first passivation film being formed to have a thickness less than a thickness of the second passivation film and greater than a thickness of the third passivation film. It will be appreciated that embodiments are not limited to the stated ratios, which are provided merely by way of example.

In one or more embodiments set forth above, a passivation layer structure includes one or more passivation layers or layers formed under similar or identical deposition conditions and, although the deposition conditions may be identical, the respective passivation layers can nonetheless be distinguished. For example, even in a case where sequential passivation layers are formed under identical conditions (e.g., where a second passivation layer is formed directly on (and thus in contact with) a first passivation layer under the same conditions used to form the first passivation layer), such that the sequential layers have a same etch rate to an etchant, a boundary between the sequential passivation layers is nonetheless detectable. Thus, each passivation layer is distinguishable and able to be assessed, e.g., in terms of shape, thickness, and the like. In some embodiments, detection of the boundary is effected using an acid soak with, e.g., an acid composed BOE 10±1:1 (612±10 ml)+98±1% acetic acid (420±10 ml)+49±1% HF (42±10 ml)+DI water (129±10 ml).

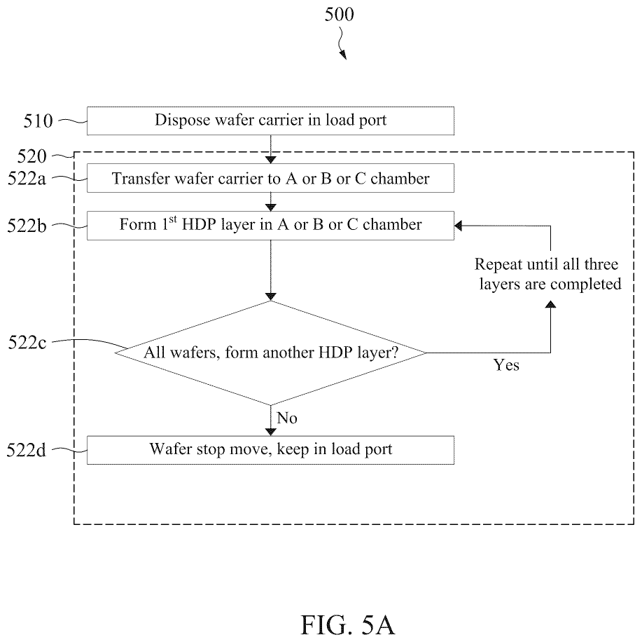

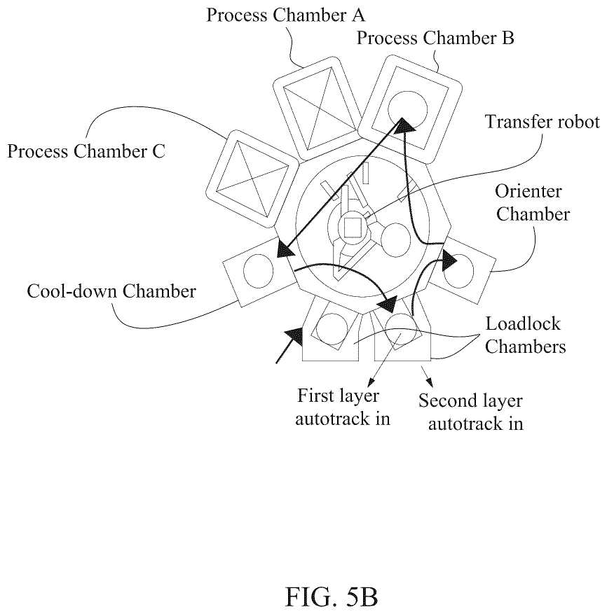

FIG. 5A is a flow chart of a method for forming a passivation layer structure, in accordance with some embodiments.

In FIG. 5A, a method 500 includes operations corresponding to block 315 of the method 300 of FIG. 3A. In block 510 of the method 500, a wafer carrier is disposed in a load port of a wafer processing apparatus that includes at least the load port and a process chamber. In the example of FIG. 5A, it is assumed that the wafer processing apparatus includes process chambers A, B, and C. One of ordinary skill in the art would understand that the use of three process chambers is merely exemplary and that other numbers of process chambers are within the scope of this description.

The method 500 continues with block 520, which includes blocks 522a-d. In block 522a, the wafer carrier is transferred to one of the process chambers A-C. In block 522b, a first passivation layer (HDP layer) is formed on the wafer or wafers from the wafer carrier in the selected one of the process chambers A-C. In block 522c, it is determined whether another of the first, second, and third passivation layers (HDP layers) remains to be formed on each wafer from the wafer carrier. If yes, the layer-forming operation of block 522b is repeated until each wafer has the first, second, and third passivation layers (HDP layers) formed thereon. If no, the layer-forming operations for the first, second, and third passivation layers (HDP layers) are complete and flow proceeds to block 522d. In block 522d, the wafers are stopped and kept in the load port.

With respect to the method 500, queue time (Q-time)-related defects can occur as a result of a delay of a processing step. Between formation of the first passivation layer and the second passivation layer, and/or between formation of the second passivation layer and the third passivation layer, Q-time considerations are relevant to the resistance of layer interfaces to separation or cracking. For example, if an SiO₂ surface, e.g., a passivation layer, is exposed to air, a layer of water-rich dioxide can form on the surface, which creates an interface layer where cracks more easily form, e.g., in the case that a metal interconnect and the passivation layer structure are pulled due to forces such as cooling-induced contraction between materials having different positive CTEs. The formation of a water-rich dioxide can occur even in a carefully controlled environment if a native oxide surface is left exposed. The method 500 helps to reduce or avoid such Q-time-related defects by minimizing processing delays between passivation layer formation steps and subsequent processing steps, and minimizing the duration of wafer surface and passivation layer exposures.

FIG. 5B is an example of a path that a wafer travels in a manufacturing tool, in accordance with some embodiments.

In FIG. 5B, a wafer processing apparatus includes loadlock chambers, an orienter chamber, process chambers A, B, and C, a cool-down chamber, and a transfer robot. The transfer robot is in a central region of the wafer processing apparatus and the chambers are arranged around the central region. The robot is configured to move a wafer carrier between the chambers. In further detail, in forming the passivation layer structure, the robot is used to move the wafer carrier from a loadlock chamber to the orienter chamber, then a selected one of the process chambers A, B, and C, then to the cool-down chamber, and then to a loadlock chamber.

In some embodiments, multiple passivation layers (e.g., each of passivation layers 126a-c) are formed in a single process chamber (i.e., one of process chambers A, B, and C). In other embodiments, one or less than all of the passivation layers is formed in one of the process chambers A, B, and C, and another or a remainder of the passivation layers is formed in another of the process chambers A, B, and C.

In FIG. 5B, the sequence of wafer processing operations used to form the passivation layer structure provides for first layer auto track in, and second layer auto track in (as compared to first layer manual track in and second layer manual track in). The first track in and the second track in are continuous. The process flow provides for three consecutive automatic runs, which can help to avoid Q-time-related defects, e.g., cracks, and can improve productivity.

Referring again to FIG. 3A, the method 300 continues with block 320 in which an oxide layer is formed on the passivation layer structure and a nitride layer is formed on the oxide layer.

Subsequently, in block 325, openings are formed in the liner, the passivation layer structure, and the oxide and nitride layers to expose tops of the interconnect structures that are in the topmost interconnect layer.

Subsequently, in block 330, under-bump metallization or under-ball metal (UBM) pads are formed on the nitride layer and in the openings, and connection bumps are formed on the UBM pads. In some embodiments, the formation of the conductive bumps includes performing a plating step to form solder regions over the UBM pads, and then reflowing the solder regions to form conductive bumps on the UBM pads.

Additional details regarding the structure and formation of the passivation layer structure are set forth in U.S. Pat. No. 8,643,151, issued Feb. 4, 2014, which is incorporated by reference herein in its entirety.

It will be appreciated that features, characteristics, and/or elements described in connection with 5A-5B are usable singly or in combination with features, characteristics, and/or elements described in connection with the liner formation of FIGS. 1-4B.

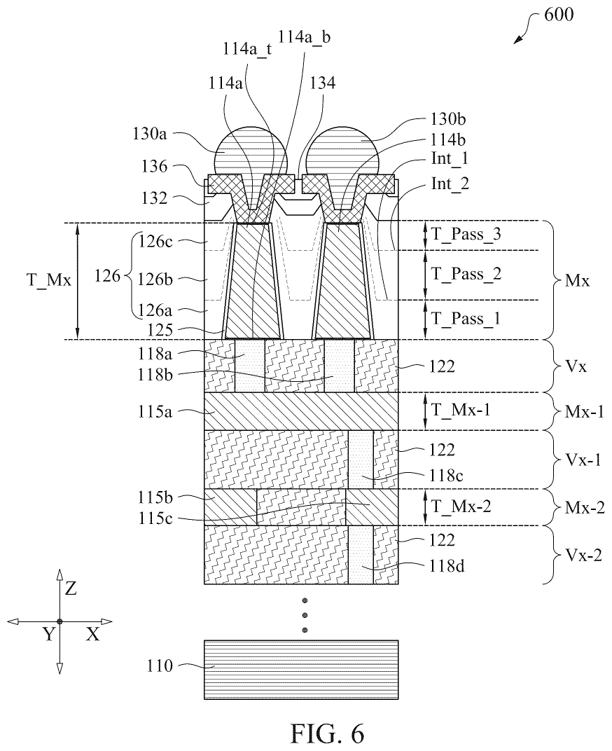

FIG. 6 is a cross-sectional view of the integrated circuit device 600 corresponding to a line I-I′ in FIG. 1, in accordance with some embodiments.

In FIG. 6, in the passivation layer structure 126, the passivation layer 126b is thicker than the passivation layer 120a, and the passivation layer 126c is thinner than the passivation layer 120a. That is, the respective thicknesses of the passivation layers 126a-c satisfy the relationship T_Pass_2>T_Pass_1>T_Pass_3. For a case in which the overall thickness of the passivation layer structure 126 is kept constant, making the passivation layer 126b thicker and making the passivation layer 126c thinner has the effect of raising the second interface Int_2.

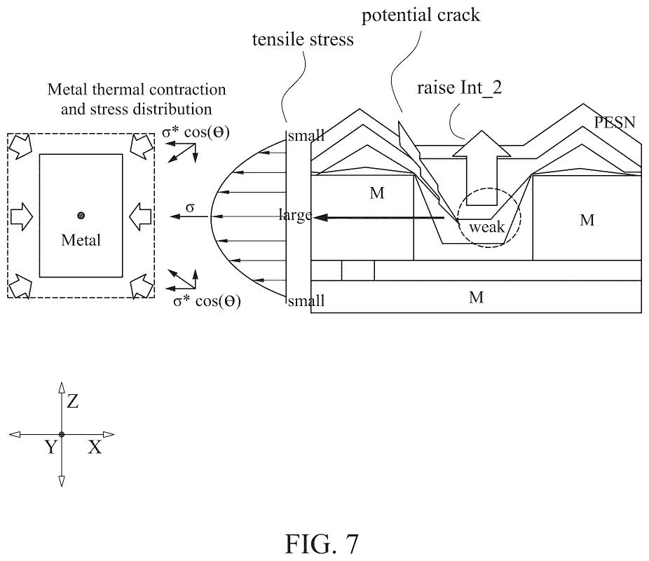

In further detail, in FIG. 6, a top 114a_t and a bottom 114a_b of the interconnect structure 114a are identified. Making the passivation layer 126b thicker and the passivation layer 126c thinner has the effect of raising the second interface Int_2 towards the top 114a_t and away from the bottom 114a_b of the interconnect structure 114a (and likewise for the interconnect structure 114b; it will be assumed that descriptions of the interconnect structure 114a also apply to the interconnect structure 114b). This increased thickness of the passivation layer 126b and decreased thickness of the passivation layer 126c, and thus the raising of the second interface Int_2, helps to avoid overlap of the interface Int_2 with a maximum stress point of the interconnect structure 114a. This is schematically illustrated in FIG. 7. In FIG. 7, the middle position (i.e., half the height) of the interconnect structure is the location of the maximum tensile stress point. The metal thermal contraction and stress distribution diagram at the left side of FIG. 7 shows four block arrows pointing at four corners of the interconnect structure and two block arrows pointing a vertical sides of the interconnect structure. Angle θ is measured at the position between the four corners and the two vertical edges of the interconnect structure. In some embodiments, the interface Int_1 has a highest extent that is below half-height of the interconnect structure 114a. In some embodiments, the interface Int_2 has a lowest extent that is above half-height of the interconnect structure 114a. In some embodiments, the interface Int_2 has a lowest extent that is about two-thirds to about four-fifths of the height of the interconnect structure 114a.

In an example case in which the interconnect structure 114a is an aluminum interconnect structure having a CTE of about 25 ppm/° C. and the passivation layer structure 126 is silicon oxide having a CTE of about 0.5 ppm/° C., stresses from heating-induced expansion and cooling-induced contraction are reduced in the IC device 600 relative to a device in which the second interface Int_2 is closer to a mid-height of the interconnect structure 114a.

The IC device 600 thus reduces strain on the passivation layer structure 126 and reduces the possibility of cracks developing within the passivation layer structure 126 itself, and/or between the passivation layer structure 126 and the interconnect structures 114a and 114b, upon heating-induced expansion and/or cooling-induced contraction, relative to a device in which the second interface Int_2 is lower and closer to a maximum stress point of the interconnect structures 114a and 114b. This is particularly important as the thickness T_Mx is increased and the thickness of the passivation layer structure is correspondingly increased for an IC device having a UTM layer. The IC device 600 provides for the use of an ultra-thick metal package wiring layer and a correspondingly thicker passivation layer, helping to ensure that the IC device is protected against scratching, water vapor-induced corrosion, and the like. Further, the IC device 600 helps to prevent cracking due to strong stresses from the ultra-thick metal in the wiring layer that cause the metal to produce more tensile stress on the passivation layer.

It will be appreciated that features, characteristics, and/or elements described in connection with FIGS. 6-7 are usable singly or in combination with features, characteristics, and/or elements described in connection with the liner formation of FIGS. 1-4B and/or in connection with the Q-time control of FIGS. 5A-5B.

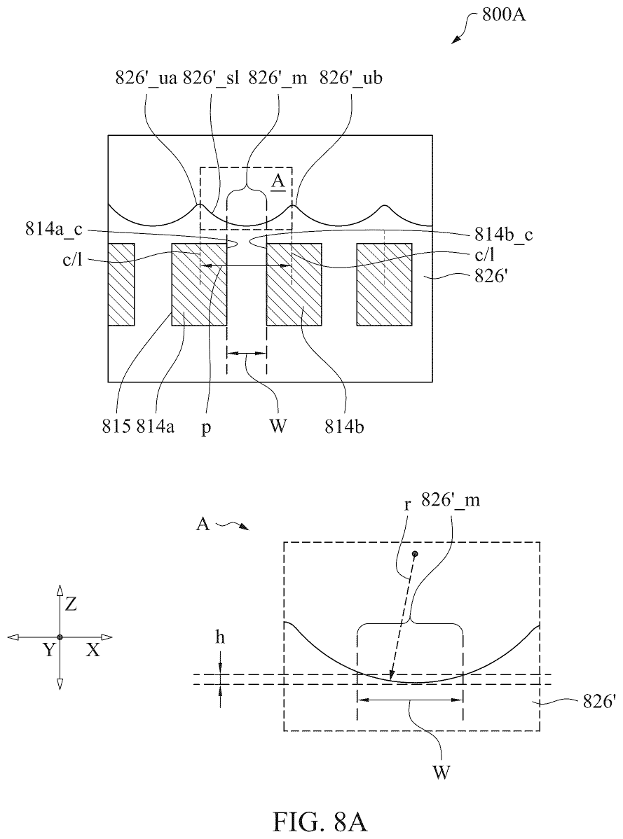

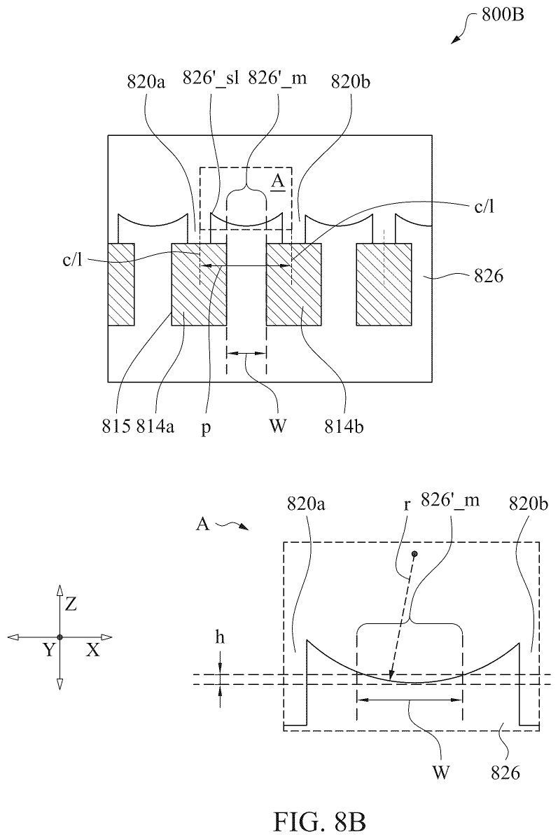

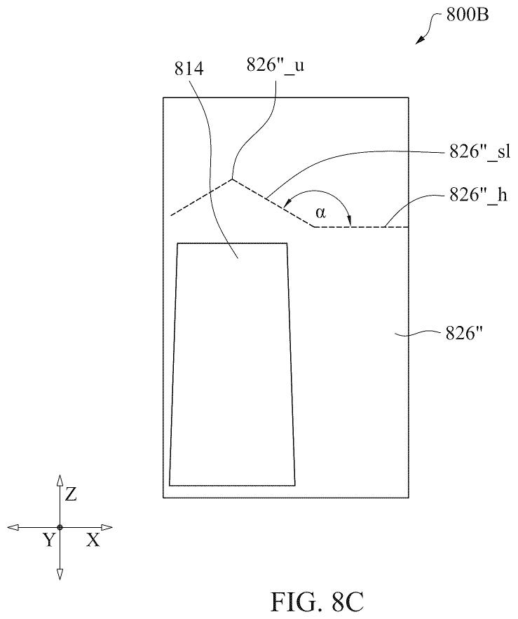

FIG. 8A is a schematic cross-sectional view of an intermediate structure 800A of an integrated circuit device, in accordance with some embodiments. FIG. 8A includes an inset showing an enlargement of a region A of the intermediate structure 800A.

In FIG. 8A, the intermediate structure 800A includes UTM interconnect structures 814a and 814b corresponding to the interconnect structures 114a and 114b described above. A pitch p of the interconnect structures 814a and 814b is a distance between a centerline c/l of the interconnect structure 814a and a centerline c/l of the interconnect structure 814b. In FIG. 8A, structures that underlie the interconnect structures 814a and 814b, e.g., underlying interconnect layers, via layers, insulating materials, and the like, are omitted for clarity.

In forming the intermediate structure 800A, a passivation layer structure 826′ is formed on the interconnect structures 814a and 814b. In some embodiments, the passivation layer structure 826′ includes one passivation layer, two passivation layers, or more than two passivation layers. In some embodiments, the passivation layer structure 826′ includes three passivation layers corresponding to the passivation layers 126a-c. Before forming the passivation layer structure 826′, a liner 815 (corresponding to the liner 125) is formed, without using bias, on sidewalls and tops of the interconnect structures 814a and 814b, such that the liner 815 is between the interconnect structures 814a and 814b and the passivation layer structure 826′.

In the intermediate structure 800A, the passivation layer structure 826′ has an upper region 826′_ua above the interconnect structure 814a and located at about the centerline c/l of the interconnect structure 814a. The passivation layer structure 826′ also has an upper region 826′_ub above the interconnect structure 814b and located at about the centerline c/l of the interconnect structure 814b. The passivation layer structure 826′ also has a sloped region 826′_sl extending between the upper region 826′_ua and the upper region 826′_ub. The sloped region 826′_sl includes a middle region 826′_m. The middle region 826′_m extends from a point vertically aligned with a corner 814a_c of the interconnect structure 814a to a point vertically aligned with a corner 814b_c of the interconnect structure 814b.

In FIG. 8A, a profile (in cross-section) of the sloped region 826′_sl is generally concave, with the middle region 826′_m having a generally broad and smooth shape and being lower than the upper regions 826′_ua and 826′_ub. The middle region 826′_m is a relatively broad, smooth region rather than a sharper or more acute V-shaped region, which reduces sharpness of a shoulder in an HDP material formed in the passivation layer structure, helping to reduce stress concentrations in the HDP material. In some embodiments, a bulk layer of SiO₂ having a generally concave upper surface is formed by HDP CVD using D/S=2.8.

In some embodiments, a radius of curvature of the middle region 826′_m is about 0.5× the pitch p or more (about 0.5p or more), e.g., 0.8p or more. In some embodiments, forming the radius of curvature of the middle region 826′_m to be about 0.5p or more forms a relatively broad, smooth region of the passivation layer structure between the interconnect structures 814a and 814b, helping to avoid stress concentration, and helping to prevent cracks from occurring in the passivation layer structure and/or helping to prevent separation of the passivation layer structure from the interconnect structure in a UTM layer.

In some embodiments, an overall change in height h (Z-axis direction) of the middle region 826′_m is about 25% or less of a width w (X-axis direction) of the middle region 826′_m, e.g., about 10% or less of the width w (i.e., h/w is about 0.25 or less, e.g., h/w is about 0.1 or less). In some embodiments, forming the passivation layer structure to have a middle region with a change in height that is about 25% or less of the width w creates a relatively broad, smooth region of the passivation layer structure between the interconnect structures 814a and 814b, helping to avoid stress concentration, and helping to prevent cracks from occurring in the passivation layer structure and/or helping to prevent separation of the passivation layer structure from the interconnect structure in a UTM layer.

FIG. 8B is a schematic cross-sectional view of an intermediate structure 800B of an integrated circuit device, in accordance with some embodiments. FIG. 8B includes an inset showing an enlargement of a region A of the intermediate structure 800B.

Referring to intermediate structure 800B in FIG. 8B, the intermediate structure 800A of FIG. 8A is processed to form recesses 820a and 820b. The passivation layer structure having the recesses 820a and 820b therein is denoted as passivation layer structure 826 (i.e., no prime symbol (′)) in FIG. 8B. In some embodiments, forming the recesses 820a and 820b includes a photolithography process that includes depositing a photoresist layer on the passivation layer structure 826′, patterning the photoresist layer to form openings in the photoresist layer located above where the recesses 820a and 820b are to be formed, etching the passivation layer structure 826′ through the openings in the photoresist layer to form recess 820a located above the interconnect structure 814a and recess 820b located above the interconnect structure 814b, and etching the liner 815 to expose upper surfaces of the interconnect structures 814a and 814b.

In FIG. 8B, the recesses 820a and 820b in the passivation layer structure 826 are vertically aligned with the interconnect structures 814a and 814b. Under-bump metallization or under-ball metal (UBM) pads are formed in the recesses 820a and 820b in subsequent processing operations, and conductive bumps are formed on the under-bump metallization or under-ball metal (UBM) pads (see FIGS. 2 and 6). Forming the recesses 820a and 820b removes portions of or all of the upper region 826′_ua and the upper region 826′_ub, but does not remove the middle region 826′_m, such that shape and the radius of curvature of the middle region 826′_m of the passivation layer structure 826 are evident in the final IC device.

It will be appreciated that features, characteristics, and/or elements described in connection with FIGS. 8A-B are usable singly or in combination with features, characteristics, and/or elements described in connection with the liner formation of FIGS. 1-4B, and/or in connection with the Q-time control of FIGS. 5A-5B, and/or in connection with the passivation layer thicknesses of FIGS. 6-7.

FIG. 8C is a schematic cross-sectional view of an intermediate structure 800C of an integrated circuit device, in accordance with some embodiments.

In FIG. 8C, the intermediate structure 800C includes a UTM interconnect structure 814 corresponding to the interconnect structure 114 described above. In FIG. 8C, structures that underlie the interconnect structure 814, e.g., underlying interconnect layers, via layers, insulating materials, and the like, are omitted for clarity.

In forming the intermediate structure 800C, a passivation layer structure 826″ is formed on the interconnect structure 814. In some embodiments, the passivation layer structure 826″ includes a plurality of passivation layers, e.g., corresponding to the passivation layers 126a-c. In some embodiments, before forming the passivation layer structure 826″, a liner (corresponding to the liner 125) is formed, without using bias, on sidewalls and the top of the interconnect structure 814, such that the liner is between the interconnect structure 814 and the passivation layer structure 826″.

In the intermediate structure 800C, the passivation layer structure 826″ has a peaked, roof-like upper region 826″ _u and a sloped region 826″ _sl. The sloped region 826″ _sl forms an obtuse angle α relative to a horizontal region 826″ _h of the passivation layer structure 826″. In FIG. 8C, the horizontal region 826″ _h is a lowermost extent of the upper surface of the passivation layer structure 826″, and is higher than an uppermost extent of the interconnect structure 814. In other embodiments, the lowermost extent of the passivation layer structure 826″ is at an even height with or below the top of the interconnect structure 814.

In some embodiments, the angle α is greater than 135°, e.g., about 150°. In some embodiments, maintaining the angle α greater than 1350 helps to avoid stress concentration and helps to prevent cracks from occurring in the passivation layer structure. In some embodiments, the angle α is about 150°, e.g., 150±5°. The angle α is determined by, among other things, deposition conditions used to form the passivation layer structure 826″. Table 2 below is an example of deposition conditions for forming the passivation layer structure 826″ to have the angle α of about 150°.

TABLE 2

| Operation | Bulk layer (n1) |
|---|---|
| 1^{st} | D/S = 2.8 + 2.8 + 3.6 |
| 2^{nd} | D/S = 2.8 + 2.8 + 3.6 |
| 3^{rd} | D/S = 2.8 + 2.8 + 3.6 |

In Table 2, D/S refers to deposition rate/sputter rate. Note n1: bulk layer is SiO₂ formed by HDP CVD; D/S 2.8+2.8+3.6 indicates that HDP layer-forming operation is three steps, as follows. First, using D/S=2.8 to form a first film. Next, using D/S=2.8 to form a second film. Next, using D/S=3.6 to form a third film.

In some embodiments, the D/S used to form the third film is 2 or more and less than 6, e.g., 3.0 to 4.2, e.g., 3.2 to 4.0. Maintaining a D/S of 2 or more and less than 6 for the third film helps to prevent cracks from occurring in the passivation layer structure 826′. A D/S of less than 2 can reduce production capacity without providing further reductions in the occurrence of cracks. A DS of 6 or more can increase the occurrence of cracking.

Without being bound by theory, it is believed that the deposition condition of 3.6 stated in Table 1 is particularly relevant to controlling the angle α to be greater than 135°, e.g., to be about 150°, and that a shape change in the HDP oxide (at an upper corner of the interconnect structure) is less sharp, and less prone to generate or concentrate stresses that can lead to cracking of the passivation layer structure and/or separation of the passivation layer structure from the interconnect structure in a UTM layer formed as a topmost interconnect layer.

In some embodiments, evaluation of the angle α and/or evaluating cracking of the passivation layer are done using SEM and visualizing the profile of the passivation layer structure using the acid soak described above. In some embodiments, cracking of the passivation layer structure is determined by forming metal fuses in or on the UTM layer and evaluating open fuses as evidencing crack formation. Without being bound by theory, additional factors that determine a propensity for cracking are believed to include relatively high processing temperatures, e.g., over 360° C. (although relatively low processing temperatures can increase the possibility of other undesirable effects, e.g., bubble formation between a passivation layer and an adjacent structure or layer such as a metal layer, via, or the like).

It will be appreciated that features, characteristics, and/or elements described in connection with FIG. 8C are usable singly or in combination with features, characteristics, and/or elements described in connection with the liner formation of FIGS. 1-4B, and/or in connection with the Q-time control of FIGS. 5A-5B, and/or in connection with the passivation layer thicknesses of FIGS. 6-7, and/or in connection with the passivation layer structure profile of FIGS. 8A-B.

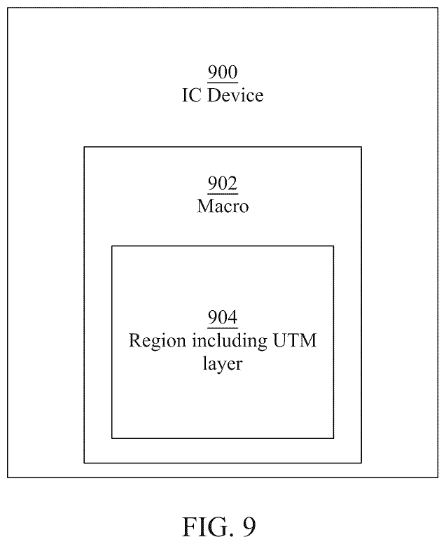

FIG. 9 is a block diagram of an IC device, in accordance with some embodiments.

In FIG. 9, an IC device 900 includes a macro 902. In some embodiments, the macro 902 includes one or more of a memory, a power grid, a cell or cells, an inverter, a latch, a buffer and/or any other type of circuit arrangement that may be represented digitally in a cell library. In some embodiments, the macro 902 is understood in the context of an analogy to the architectural hierarchy of modular programming, in which subroutines/procedures are called by a main program (or by other subroutines) to carry out a given computational function. In this context, the IC device 900 uses the macro 902 to perform one or more given functions. Accordingly, in this context and in terms of architectural hierarchy, the IC device 900 is analogous to the main program and the macro 902 is analogous to subroutines/procedures. In some embodiments, the macro 902 is a soft macro. In some embodiments, the macro 902 is a hard macro. In some embodiments, the macro 902 is a soft macro which is described digitally in register-transfer level (RTL) code. In some embodiments, synthesis, placement, and routing have yet to have been performed on the macro 902 such that the soft macro can be synthesized, placed, and routed for a variety of process nodes. In some embodiments, the macro 902 is a hard macro which is described digitally in a binary file format (e.g., Graphic Database System II (GDSII) stream format), where the binary file format represents planar geometric shapes, text labels, other information, and the like of one or more layouts of the macro 902 in hierarchical form. In some embodiments, synthesis, placement, and routing have been performed on the macro 902 such that the hard macro is specific to a particular process node. In FIG. 9, the macro 902 includes a region 904 that includes a UTM layer that includes one or more ultra-thick interconnect structures, e.g., corresponding to the interconnect structures 114 and 614 described above, at a topmost layer of interconnect structures, vias, insulating layers, and the like. The region 904 includes liners and passivation layer structures, e.g., corresponding to the liner 125 and the passivation layer structures 126 and 616 described above, on the interconnect structures of the UTM layer.

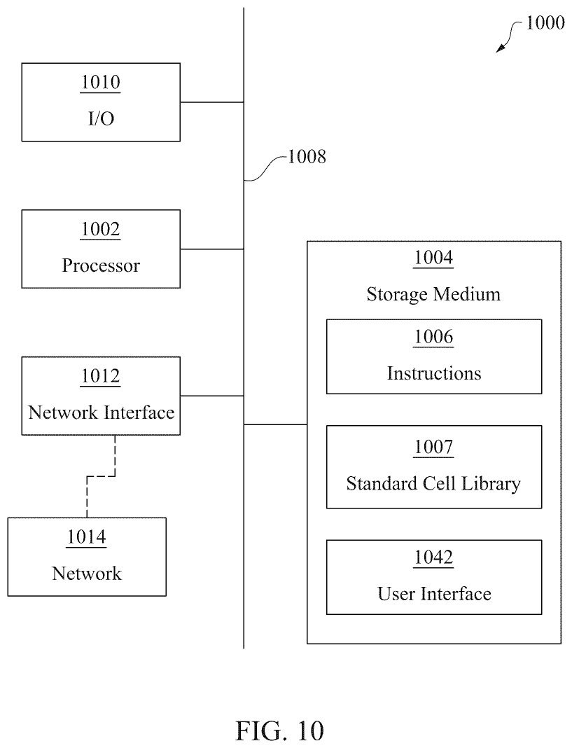

FIG. 10 is a block diagram of an electronic design automation (EDA) system 1000 in accordance with some embodiments.

In some embodiments, EDA system 1000 includes an Automatic Place & Route (APR) system. Methods described herein of designing layouts represent wire routing arrangements, in accordance with one or more embodiments, are implementable, for example, using EDA system 1000, in accordance with some embodiments.

In some embodiments, EDA system 1000 is a general-purpose computing device including a hardware processor 1002 and a non-transitory, computer-readable storage medium 1004. The computer-readable storage medium 1004, amongst other things, is encoded with, i.e., stores, computer program code 1006, i.e., a set of executable instructions. Execution of instructions 1006 by the processor 1002 represents (at least in part) an EDA tool which implements a portion or all of the methods described herein in accordance with one or more embodiments (hereinafter, the noted processes and/or methods).

The processor 1002 is electrically coupled to the computer-readable storage medium 1004 via a bus 1008. The processor 1002 is also electrically coupled to an I/O interface 1010 by the bus 1008. A network interface 1012 is also electrically connected to processor 1002 via the bus 1008. Network interface 1012 is connected to a network 1014, so that the processor 1002 and the computer-readable storage medium 1004 are capable of connecting to external elements via network 1014. Processor 1002 is configured to execute computer program code 1006 encoded in the computer-readable storage medium 1004 in order to cause EDA system 1000 to be usable for performing a portion or all of the noted processes and/or methods. In one or more embodiments, processor 1002 is a central processing unit (CPU), a multi-processor, a distributed processing system, an application specific integrated circuit (ASIC), and/or a suitable processing unit.

In one or more embodiments, the computer-readable storage medium 1004 is an electronic, magnetic, optical, electromagnetic, infrared, and/or a semiconductor system (or apparatus or device). Examples of the computer-readable storage medium 1004 include a semiconductor or solid-state memory, a magnetic tape, a removable computer diskette, a random access memory (RAM), a read-only memory (ROM), a rigid magnetic disk, and/or an optical disk. In one or more embodiments using optical disks, the computer-readable storage medium 1004 includes a compact disk read-only memory (CD-ROM), a compact disk-read/write (CD-R/W), and/or a digital video disc (DVD).

In one or more embodiments, the computer-readable storage medium 1004 stores computer program code 1006 configured to cause EDA system 1000 (where such execution represents (at least in part) the EDA tool) to be usable for performing a portion or all of the noted processes and/or methods. In one or more embodiments, the computer-readable storage medium 1004 also stores information which facilitates performing a portion or all of the noted processes and/or methods. In one or more embodiments, the computer-readable storage medium 1004 stores library 1007 of standard cells including such standard cells as disclosed herein.

The EDA system 1000 includes I/O interface 1010. I/O interface 1010 is coupled to external circuitry. In one or more embodiments, I/O interface 1010 includes a keyboard, keypad, mouse, trackball, trackpad, touchscreen, and/or cursor direction keys for communicating information and commands to processor 1002.

The EDA system 1000 also includes network interface 1012 coupled to processor 1002. Network interface 1012 allows EDA system 1000 to communicate with network 1014, to which one or more other computer systems are connected. Network interface 1012 includes wireless network interfaces such as BLUETOOTH, WIFI, WIMAX, GPRS, or WCDMA; or wired network interfaces such as ETHERNET, USB, or IEEE-1364. In one or more embodiments, a portion or all of noted processes and/or methods, is implemented in two or more EDA systems 1000.

The EDA system 1000 is configured to receive information through I/O interface 1010. The information received through I/O interface 1010 includes one or more of instructions, data, design rules, libraries of standard cells, and/or other parameters for processing by processor 1002. The information is transferred to processor 1002 via the bus 1008. EDA system 1000 is configured to receive information related to a user interface (UI) through I/O interface 1010. The information is stored in the computer-readable storage medium 1004 as user interface (UI) 1042.

In some embodiments, a portion or all of the noted processes and/or methods is implemented as a standalone software application for execution by a processor. In some embodiments, a portion or all of the noted processes and/or methods is implemented as a software application that is a part of an additional software application. In some embodiments, a portion or all of the noted processes and/or methods is implemented as a plug-in to a software application. In some embodiments, at least one of the noted processes and/or methods is implemented as a software application that is a portion of an EDA tool. In some embodiments, a portion or all of the noted processes and/or methods is implemented as a software application that is used by EDA system 1000. In some embodiments, a layout that includes standard cells is generated using a tool such as VIRTUOSO® available from Cadence Design Systems, Inc., or another suitable layout generating tool.

In some embodiments, the processes are realized as functions of a program stored in a non-transitory computer readable recording medium. Examples of a non-transitory computer readable recording medium include, but are not limited to, external/removable and/or internal/built-in storage or memory unit, e.g., one or more of an optical disk, such as a DVD, a magnetic disk, such as a hard disk, a semiconductor memory, such as a ROM, a RAM, a memory card, and the like.

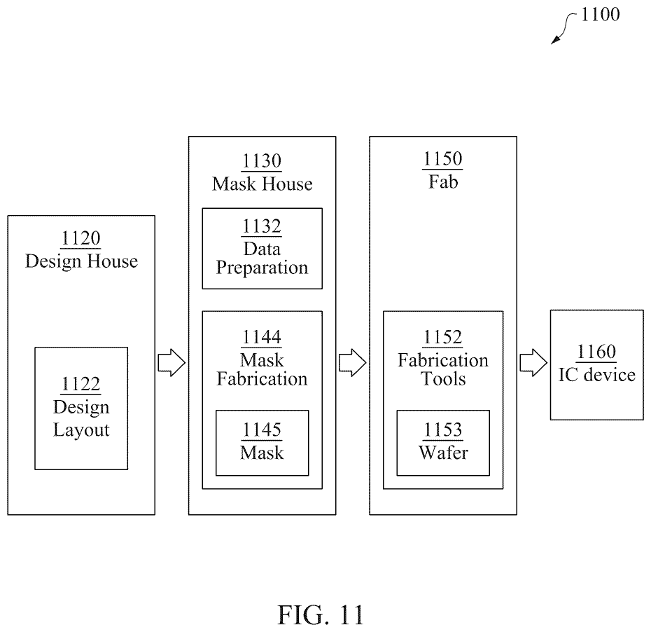

FIG. 11 is a block diagram of an integrated circuit (IC) manufacturing system 1100, and an IC manufacturing flow associated therewith, in accordance with some embodiments. In some embodiments, based on a layout, at least one of (A) one or more semiconductor masks or (B) at least one component in a layer of a semiconductor integrated circuit is fabricated using the IC manufacturing system 1100.

In FIG. 11, the IC manufacturing system 1100 includes entities, such as a design house 1120, a mask house 1130, and an IC manufacturer/fabricator (fab) 1150, that interact with one another in the design, development, and manufacturing cycles and/or services related to manufacturing an IC device 1160, e.g., corresponding to the IC devices 100, 600, 800 described above. The entities in the IC manufacturing system 1100 are connected by a communications network. In some embodiments, the communications network is a single network. In some embodiments, the communications network is a variety of different networks, such as an intranet and the Internet. The communications network includes wired and/or wireless communication channels. Each entity interacts with one or more of the other entities and provides services to and/or receives services from one or more of the other entities. In some embodiments, two or more of the design house 1120, the mask house 1130, and the IC fab 1150 are owned by a single larger company. In some embodiments, two or more of the design house 1120, the mask house 1130, and the IC fab 1150 coexist in a common facility and use common resources.

The design house (or design team) 1120 generates an IC design layout 1122. The IC design layout 1122 includes various geometrical patterns designed for an IC device 1160. The geometrical patterns correspond to patterns of metal, oxide, or semiconductor layers that make up the various components of the IC device 1160 to be fabricated. The various layers combine to form various IC features. For example, a portion of the IC design layout 1122 includes various IC features, such as an active region, gate electrode, source and drain, metal lines or vias of an interlayer interconnect, UTM interconnect structure, passivation layer structures, openings for bonding pads, and conductive bumps to be formed in a semiconductor substrate (such as a silicon wafer) and various material layers disposed on the semiconductor substrate, or the like. The design house 1120 implements a formal design procedure to form the IC design layout 1122. The design procedure includes one or more of logic design, physical design or place-and-route operation. The IC design layout 1122 is presented in one or more data files having information of the geometrical patterns. For example, the IC design layout 1122 can be expressed in a GDSII file format or DFII file format.

The mask house 1130 includes mask data preparation 1132 and mask fabrication 1144. The mask house 1130 uses the IC design layout 1122 to manufacture one or more masks 1145 to be used for fabricating the various layers of the IC device 1160 according to the IC design layout 1122. The mask house 1130 performs the mask data preparation 1132, where the IC design layout 1122 is translated into a representative data file (RDF). The mask data preparation 1132 provides the RDF to the mask fabrication 1144. The mask fabrication 1144 includes a mask writer. The mask writer converts the RDF to an image on a substrate, such as a mask (reticle) 1145 or a semiconductor wafer 1153. The IC design layout 1122 is manipulated by the mask data preparation 1132 to comply with particular characteristics of the mask writer and/or requirements of the IC fab 1150. In FIG. 11, the mask data preparation 1132 and the mask fabrication 1144 are illustrated as separate elements. In some embodiments, the mask data preparation 1132 and the mask fabrication 1144 can be collectively referred to as mask data preparation.

In some embodiments, the mask data preparation 1132 includes optical proximity correction (OPC) that uses lithography enhancement techniques to compensate for image errors, such as those that can arise from diffraction, interference, other process effects and the like. The OPC adjusts the IC design layout 1122. In some embodiments, the mask data preparation 1132 includes further resolution enhancement techniques (RET), such as off-axis illumination, sub-resolution assist features, phase-shifting masks, other suitable techniques, and the like or combinations thereof. In some embodiments, inverse lithography technology (ILT) is also used, which treats OPC as an inverse imaging problem.

In some embodiments, the mask data preparation 1132 includes a mask rule checker (MRC) that checks the IC design layout 1122 that has undergone processes in the OPC with a set of mask creation rules containing geometric and/or connectivity restrictions to ensure sufficient margins, to account for variability in semiconductor manufacturing processes, and the like. In some embodiments, the MRC modifies the IC design layout 1122 to compensate for limitations during the mask fabrication 1144, which may undo part of the modifications performed by OPC in order to meet mask creation rules.

In some embodiments, the mask data preparation 1132 includes lithography process checking (LPC) that simulates processing that will be implemented by the IC fab 1150 to fabricate the IC device 1160. The LPC simulates this processing based on the IC design layout 1122 to create a simulated manufactured device, such as the IC device 1160. The processing parameters in LPC simulation can include parameters associated with various processes of the IC manufacturing cycle, parameters associated with tools used for manufacturing the IC, and/or other aspects of the manufacturing process. The LPC takes into account various factors, such as aerial image contrast, depth of focus (DOF), mask error enhancement factor (MEEF), other suitable factors, and the like or combinations thereof. In some embodiments, after a simulated manufactured device has been created by LPC, if the simulated device is not close enough in shape to satisfy design rules, OPC and/or MRC are repeated to further refine the IC design layout 1122.

It should be understood that the above description of the mask data preparation 1132 has been simplified for the purposes of clarity. In some embodiments, the mask data preparation 1132 includes additional features such as a logic operation (LOP) to modify the IC design layout 1122 according to manufacturing rules. Additionally, the processes applied to the IC design layout 1122 during the mask data preparation 1132 may be executed in a variety of different orders.

After the mask data preparation 1132 and during the mask fabrication 1144, a mask 1145 or a group of masks 1145 are fabricated based on the modified IC design layout 1122. In some embodiments, the mask fabrication 1144 includes performing one or more lithographic exposures based on the IC design layout 1122. In some embodiments, an electron-beam (e-beam) or a mechanism of multiple e-beams is used to form a pattern on a mask (photomask or reticle) 1145 based on the modified IC design layout 1122. The mask 1145 can be formed in various technologies. In some embodiments, the mask 1145 is formed using binary technology. In some embodiments, a mask pattern includes opaque regions and transparent regions. A radiation beam, such as an ultraviolet (UV) beam, used to expose the image sensitive material layer (e.g., photoresist) which has been coated on a wafer, is blocked by the opaque region and transmits through the transparent regions. In one example, a binary mask version of the mask 1145 includes a transparent substrate (e.g., fused quartz) and an opaque material (e.g., chromium) coated in the opaque regions of the binary mask. In another example, the mask 1145 is formed using a phase shift technology. In a phase shift mask (PSM) version of the mask 1145, various features in the pattern formed on the phase shift mask are configured to have proper phase difference to enhance the resolution and imaging quality. In various examples, the phase shift mask can be attenuated PSM or alternating PSM. The mask(s) generated by the mask fabrication 1144 is used in a variety of processes. For example, such a mask(s) is used in an ion implantation process to form various doped regions in a semiconductor wafer 1153, in an etching process to form various etching regions in the semiconductor wafer 1153, and/or in other suitable processes.

The IC fab 1150 is an IC fabrication business that includes one or more manufacturing facilities for the fabrication of a variety of different IC products. In some embodiments, the IC fab 1150 is a semiconductor foundry. For example, there may be a manufacturing facility for the front end fabrication of a plurality of IC products (front-end-of-line (FEOL) fabrication), while a second manufacturing facility may provide the back end fabrication for the interconnect and packaging of the IC products (back-end-of-line (BEOL) fabrication), and a third manufacturing facility may provide other services for the foundry business.

The IC fab 1150 includes fabrication tools 1152 configured to execute various manufacturing operations on semiconductor wafer 1153 such that the IC device 1160 is fabricated in accordance with the mask(s), e.g., the mask 1145. In various embodiments, the fabrication tools 1152 include one or more of a wafer stepper, an ion implanter, a photoresist coater, a process chamber, e.g., a CVD chamber or LPCVD furnace, a CMP system, a plasma etch system, a wafer cleaning system, or other manufacturing equipment capable of performing one or more suitable manufacturing processes as discussed herein.

The IC fab 1150 uses the mask(s) 1145 fabricated by the mask house 1130 to fabricate the IC device 1160. Thus, the IC fab 1150 at least indirectly uses the IC design layout 1122 to fabricate the IC device 1160. In some embodiments, the semiconductor wafer 1153 is fabricated by the IC fab 1150 using the mask(s) 1145 to form the IC device 1160. In some embodiments, the IC fabrication includes performing one or more lithographic exposures based at least indirectly on the IC design layout 1122. The semiconductor wafer 1153 includes a silicon substrate or other proper substrate having material layers formed thereon. The semiconductor wafer 1153 further includes one or more of various doped regions, dielectric features, multilevel interconnects, and the like (formed at subsequent manufacturing steps).

Details regarding an integrated circuit (IC) manufacturing system (e.g., the IC manufacturing system 1100 of FIG. 11), and an IC manufacturing flow associated therewith are found, e.g., in U.S. Pat. No. 9,256,709, granted Feb. 9, 2016, U.S. Pre-Grant Publication No. 2015/0278429, published Oct. 1, 2015, U.S. Pre-Grant Publication No. 2014/0040838, published Feb. 6, 2014, and U.S. Pat. No. 7,260,442, granted Aug. 21, 2007, the entireties of each of which are hereby incorporated by reference.

It will be appreciated that features, characteristics, and/or elements described in connection with a particular embodiment are usable singly or in combination with features, characteristics, and/or elements described in connection with one or more other embodiments unless otherwise specifically indicated.

In some embodiments, an integrated circuit (IC) device includes an interconnect layer including a first interconnect structure and a second interconnect structure spaced apart from the first interconnect structure in a first direction, the first interconnect structure and the second interconnect structure being arranged at a first pitch in the first direction; and a passivation structure on the first interconnect structure and the second interconnect structure. The passivation structure includes a first recess over the first interconnect structure; a second recess over the second interconnect structure; and a sloped region extending from the first recess to the second recess. A radius of curvature of a middle region of the sloped region is at least 0.5 times the first pitch.

In some embodiments, the first interconnect structure has a first corner, the second interconnect structure has a second corner facing the first corner, and the middle region has the radius of curvature of at least 0.5 times the first pitch from a first point that is vertically aligned with the first corner to a second point that is vertically aligned with the second corner. In some embodiments, the first interconnect structure has a first corner, the second interconnect structure has a second corner facing the first corner, the first corner and the second corner are spaced apart by a first distance in the first direction, and the middle region has the radius of curvature of at least 0.5 times the first pitch throughout the first distance. In some embodiments, the first interconnect structure has a first corner, the second interconnect structure has a second corner facing the first corner, the first corner and the second corner are spaced apart by a first distance in the first direction, and an overall change in height of the middle region across the first distance is about 25% or less of the first distance. In some embodiments, the overall change in the height of the middle region across the first distance is about 10% or less of the first distance. In some embodiments, the first distance is less than the first pitch. In some embodiments, the middle region extends from a first point that is vertically aligned with the first corner to a second point that is vertically aligned with the second corner. In some embodiments, the passivation structure includes a plurality of passivation layers, and the sloped region is part of an upper surface of an uppermost passivation layer of the plurality of passivation layers. In some embodiments, a lowermost extent of an upper surface of the passivation structure is above an uppermost extent of the first interconnect structure and the second interconnect structure.

In some embodiments, an integrated circuit (IC) device includes an interconnect layer including a first interconnect structure and a second interconnect structure; and a passivation structure on the first interconnect structure and the second interconnect structure. The first interconnect structure and the second interconnect structure are arranged at a first pitch in a first direction, the first interconnect structure has a first corner, the second interconnect structure has a second corner facing the first corner, the first corner and the second corner are spaced apart by a first distance in the first direction, the passivation structure includes: a first recess over the first interconnect structure; a second recess over the second interconnect structure; and an upper surface having a sloped region extending from the first recess to the second recess, a lowermost extent of the upper surface is above the first corner and the second corner, and an overall change in height of a middle region of the sloped region is about 25% or less of the first distance. In some embodiments, the overall change in the height of the middle region is about 10% or less of the first distance. In some embodiments, the first distance is less than the first pitch. In some embodiments, the middle region extends from a first point that is vertically aligned with the first corner to a second point that is vertically aligned with the second corner. In some embodiments, the middle region has a radius of curvature of at least 0.5 times the first pitch from the first point to the second point. In some embodiments, the passivation structure includes a plurality of passivation layers, and the sloped region is part of an upper surface of an uppermost passivation layer of the plurality of passivation layers.

In some embodiments, a method of fabricating an integrated circuit (IC) device includes forming an interconnect layer, including forming a first interconnect structure and forming a second interconnect structure spaced apart from the first interconnect structure in a first direction, the first interconnect structure and the second interconnect structure being formed to have a first pitch in the first direction; and forming a passivation structure on the first interconnect structure and the second interconnect structure. The forming a passivation structure includes: forming a first recess in the passivation structure, the first recess being formed over the first interconnect structure; forming a second recess in the passivation structure, the second recess being formed over the second interconnect structure; and forming the passivation structure to have a sloped region extending from the first recess to the second recess. A middle region of the sloped region is formed to have a radius of curvature that is at least 0.5 times the first pitch.

In some embodiments, the forming a first interconnect structure includes: forming the first interconnect structure to have a first corner, the forming a second interconnect structure includes: forming the second interconnect structure to have a second corner facing the first corner, and the forming a passivation structure includes: forming the middle region to have the radius of curvature of at least 0.5 times the first pitch from a first point that is vertically aligned with the first corner to a second point that is vertically aligned with the second corner. In some embodiments, the first corner and the second corner are formed to be spaced apart by a first distance in the first direction, and the forming a passivation structure includes: forming the middle region to have an overall change in height that is about 25% or less of the first distance. In some embodiments, the forming a passivation structure includes: forming the middle region to have an overall change in the height that is about 10% or less of the first distance. In some embodiments, the forming a passivation structure includes: forming a plurality of passivation layers, the sloped region is formed as part of an upper surface of an uppermost passivation layer of the plurality of passivation layers, and a lowermost extent of the upper surface is formed to be above an uppermost extent of the first interconnect structure and the second interconnect structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit (IC) device comprising:
an interconnect layer including a first interconnect structure and a second interconnect structure spaced apart from the first interconnect structure in a first direction, the first interconnect structure and the second interconnect structure being arranged at a first pitch in the first direction; and
a passivation structure on the first interconnect structure and the second interconnect structure, the passivation structure including:
a first recess over the first interconnect structure;
a second recess over the second interconnect structure; and
a sloped region extending from the first recess to the second recess,
wherein a radius of curvature of a middle region of the sloped region is at least 0.5 times the first pitch.

2. The IC device of claim 1, wherein:
the first interconnect structure has a first corner,
the second interconnect structure has a second corner facing the first corner, and
the middle region has the radius of curvature of at least 0.5 times the first pitch from a first point that is vertically aligned with the first corner to a second point that is vertically aligned with the second corner.

3. The IC device of claim 1, wherein:
the first interconnect structure has a first corner,
the second interconnect structure has a second corner facing the first corner,
the first corner and the second corner are spaced apart by a first distance in the first direction, and
the middle region has the radius of curvature of at least 0.5 times the first pitch throughout the first distance.

4. The IC device of claim 1, wherein:
the first interconnect structure has a first corner,
the second interconnect structure has a second corner facing the first corner,
the first corner and the second corner are spaced apart by a first distance in the first direction, and
an overall change in height of the middle region across the first distance is about 25% or less of the first distance.

5. The IC device of claim 4, wherein:
the overall change in the height of the middle region across the first distance is about 10% or less of the first distance.

6. The IC device of claim 4, wherein:
the first distance is less than the first pitch.

7. The IC device of claim 4, wherein:
the middle region extends from a first point that is vertically aligned with the first corner to a second point that is vertically aligned with the second corner.

8. The IC device of claim 1, wherein:
the passivation structure includes a plurality of passivation layers, and
the sloped region is part of an upper surface of an uppermost passivation layer of the plurality of passivation layers.

9. The IC device of claim 1, wherein:
a lowermost extent of an upper surface of the passivation structure is above an uppermost extent of the first interconnect structure and the second interconnect structure.

10. An integrated circuit (IC) device comprising:
an interconnect layer including a first interconnect structure and a second interconnect structure; and
a passivation structure on the first interconnect structure and the second interconnect structure, wherein:
the first interconnect structure and the second interconnect structure are arranged at a first pitch in a first direction,
the first interconnect structure has a first corner,
the second interconnect structure has a second corner facing the first corner,
the first corner and the second corner are spaced apart by a first distance in the first direction,
the passivation structure includes:
a first recess over the first interconnect structure;
a second recess over the second interconnect structure; and
an upper surface having a sloped region extending from the first recess to the second recess,
a lowermost extent of the upper surface is above the first corner and the second corner, and
an overall change in height of a middle region of the sloped region is about 25% or less of the first distance.

11. The IC device of claim 10, wherein:
the overall change in the height of the middle region is about 10% or less of the first distance.

12. The IC device of claim 10, wherein:
the first distance is less than the first pitch.

13. The IC device of claim 10, wherein:
the middle region extends from a first point that is vertically aligned with the first corner to a second point that is vertically aligned with the second corner.

14. The IC device of claim 13, wherein:
the middle region has a radius of curvature of at least 0.5 times the first pitch from the first point to the second point.

15. The IC device of claim 10, wherein:
the passivation structure includes a plurality of passivation layers, and
the sloped region is part of an upper surface of an uppermost passivation layer of the plurality of passivation layers.

16. A method of fabricating an integrated circuit (IC) device, the method comprising:
forming an interconnect layer, including forming a first interconnect structure and forming a second interconnect structure spaced apart from the first interconnect structure in a first direction, the first interconnect structure and the second interconnect structure being formed to have a first pitch in the first direction; and
forming a passivation structure on the first interconnect structure and the second interconnect structure, wherein:
the forming a passivation structure includes:
forming a first recess in the passivation structure, the first recess being formed over the first interconnect structure;
forming a second recess in the passivation structure, the second recess being formed over the second interconnect structure; and
forming the passivation structure to have a sloped region extending from the first recess to the second recess, and
a middle region of the sloped region is formed to have a radius of curvature that is at least 0.5 times the first pitch.

17. The method of claim 16, wherein:
the forming a first interconnect structure includes:
forming the first interconnect structure to have a first corner,
the forming a second interconnect structure includes:
forming the second interconnect structure to have a second corner facing the first corner, and
the forming a passivation structure includes:
forming the middle region to have the radius of curvature of at least 0.5 times the first pitch from a first point that is vertically aligned with the first corner to a second point that is vertically aligned with the second corner.

18. The method of claim 17, wherein:
the first corner and the second corner are formed to be spaced apart by a first distance in the first direction, and
the forming a passivation structure includes:
forming the middle region to have an overall change in height that is about 25% or less of the first distance.

19. The method of claim 18, wherein:
the forming a passivation structure includes:
forming the middle region to have an overall change in the height that is about 10% or less of the first distance.

20. The method of claim 16, wherein:
the forming a passivation structure includes:
forming a plurality of passivation layers,
the sloped region is formed as part of an upper surface of an uppermost passivation layer of the plurality of passivation layers, and
a lowermost extent of the upper surface is formed to be above an uppermost extent of the first interconnect structure and the second interconnect structure.
